(19) United States
(12) Patent Application Publication
(10) Pub. No.: US 2010/0314771 A1
(43) Pub. Date: Dec. 16, 2010

(54) SEMICONDUCTOR DEVICE INCLUDING AN IMPROVED LITHOGRAPHIC MARGIN

(76) Inventors: Yoshikazu HOSOMURA, Kamakura-shi (JP); Toshiki Hisada, Yokohama-shi (JP); Fumiharu Nakajima, Yokohama-shi (JP); Chikaaki Kodama, Yokohama-shi (JP)

Correspondence Address: OBLON, SPIVAK, MCCLELLAND MAIER & NEUSTADT, L.L.P., 1940 DUKE STREET, ALEXANDRIA, VA, 22314, US

(21) Appl. No.: 12/724,051

(22) Filed: Mar. 15, 2010

(30) Foreign Application Priority Data
Jun. 16, 2009 (JP) 2009-143451

(51) Int. Cl. H01L 23/535

(52) U.S. Cl. 257/773; 257/E23.168

(57) ABSTRACT

A semiconductor device includes first to third lines. The second line has a width equal to the first line. The second line is arranged with a space equal to the width from the first line, and partially has a gap. The third line is connected to one end of the first line and to a side of one end of the second line.

### CROSS-REFERENCE TO RELATED APPLICATIONS

This application is based upon and claims the benefit of priority from prior Japanese Patent Application No. 2009-143451, filed Jun. 16, 2009, the entire contents of which are incorporated herein by reference.

### BACKGROUND OF THE INVENTION

1. Field of the Invention

The present invention relates to a semiconductor device, and in particular, to its wiring structure.

2. Description of the Related Art

Semiconductor devices are used for various fields. Therefore, a semiconductor device configured to meet the following various requirements is required. For example, miniaturization of the semiconductor device, reduction of power consumption, improvement of reliability and reduction of cast are given. In particular, the semiconductor device is miniaturized; for this reason, it is required to increase the number of elements per unit area. Therefore, a higher manufacturing technique is inevitably required.

Reduction of a line width and reduction of a space between lines are given as one method of miniaturizing a semiconductor device. However, the line width and the space between lines are reduced, and thereby, it is difficult to form a pattern such as a line in the lithographic process using currently using light and an electronic wave. Particularly, in a layout pattern, there are the following various portions. For example, one is an area where the same-shaped pattern is formed. Another is a portion where a pattern width and space periodicity largely change, for example, a connection portion for lines having different line width. A pattern of the connection portion is thinned depending on an exposure condition; as a result, there is the problem that the pattern is cut off. Recently, a technique of extracting such a hotspot using lithographic simulation is developed in order to solve the problem.

Moreover, the following technique is developed (e.g., see Jpn. Pat. Appln. KOKAI Publication No. 2002-64043). According to the technique, disconnection and short-circuit of a line pattern are prevented in the boundary between a memory cell array area and a peripheral circuit area formed with a line pattern at a pitch larger than the memory cell array.

However, even if the techniques are employed, it is difficult to sufficiently secure a margin against a failure such as disconnection in an extended portion of a line, that is, a portion where the line width and pitch change.

### BRIEF SUMMARY OF THE INVENTION

According to a first aspect of the invention, there is provided a semiconductor device comprising: a first line; a second line having a width equal to the first line, the second line being arranged with a space equal to the width from the first line, and partially having a gap; and a third line connected to one end of the first line and connected to a side of one end of the second line.

According to a second aspect of the invention, there is provided a semiconductor device comprising: a first line functioning as a first bit line, the first line partially having a gap; a second line functioning as a second bit line having a width equal to the first line, the second line being arranged with a space equal to the width from the first line, and partially having a gap; a third line connected to one end of the first line and connected to a side of one end of the second line, the other end of the second line being not electrically connected to the third line by the gap; a fourth line connected to the other end of the second line and connected to a side of one end of the first line, the other end of the first line being not electrically connected to the fourth line by the gap; a first circuit connected to the third line; and a second circuit connected to the fourth line.

### BRIEF DESCRIPTION OF THE SEVERAL VIEWS OF THE DRAWING

FIG. 1 is a view showing a mask pattern according to a first embodiment;

FIG. 2 is a view showing a line pattern corresponding to FIG. 1 obtained using an optical simulation;

FIG. 3 is a view showing a mask pattern according to a second embodiment;

FIG. 4 is a view showing a line pattern corresponding to FIG. 3 obtained using an optical simulation;

FIG. 5 is a view showing a mask pattern according to a third embodiment;

FIG. 6 is a view showing a mask pattern according to a fourth embodiment;

FIG. 7 relates to a fifth embodiment, and is a view showing the case where the configuration shown in the second embodiment is applied to a bit line of a semiconductor memory device;

FIG. 8 is a view showing the case where the configuration shown in the second embodiment is applied to a word line of a semiconductor memory device;

FIG. 9 is a view showing one example of the line structure of a semiconductor memory device according to a sixth embodiment;

FIG. 10 is a perspective view showing a part of the line structure shown in FIG. 9;

FIG. 11 is a plan view showing the configuration of FIG. 10;

FIG. 12 is a plan view showing a modification example of the sixth embodiment;

FIGS. 13A, 13B, 13C and 13D are plan views showing a part of FIG. 9;

FIG. 14 is a view to explain the relationship between a line width and a space in a processed pattern of a line; and

FIG. 15 is a view to explain the relationship of the design rule related to a line width and a space.

### DETAILED DESCRIPTION OF THE INVENTION

Various embodiments of the present invention will be hereinafter described with reference to the accompanying drawings. In the following embodiments, the same reference numerals are used to designate the identical portions.

For example, in the following layout, there is a portion where periodicity changes in a layout pattern. According to the layout, lines are extended at a double pitch from a plurality of lines arranged at a fixed pitch. In this case, the following matter has been known by lithographic simulation. Namely, the probability of generating a hotspot occurs in the portion where periodicity changes is high.

In the lithographic process, an exposure apparatus and its illumination are controlled so that a line (hereinafter, referred to as a line) width and a margin of a line having an equal space width between lines are secured best.

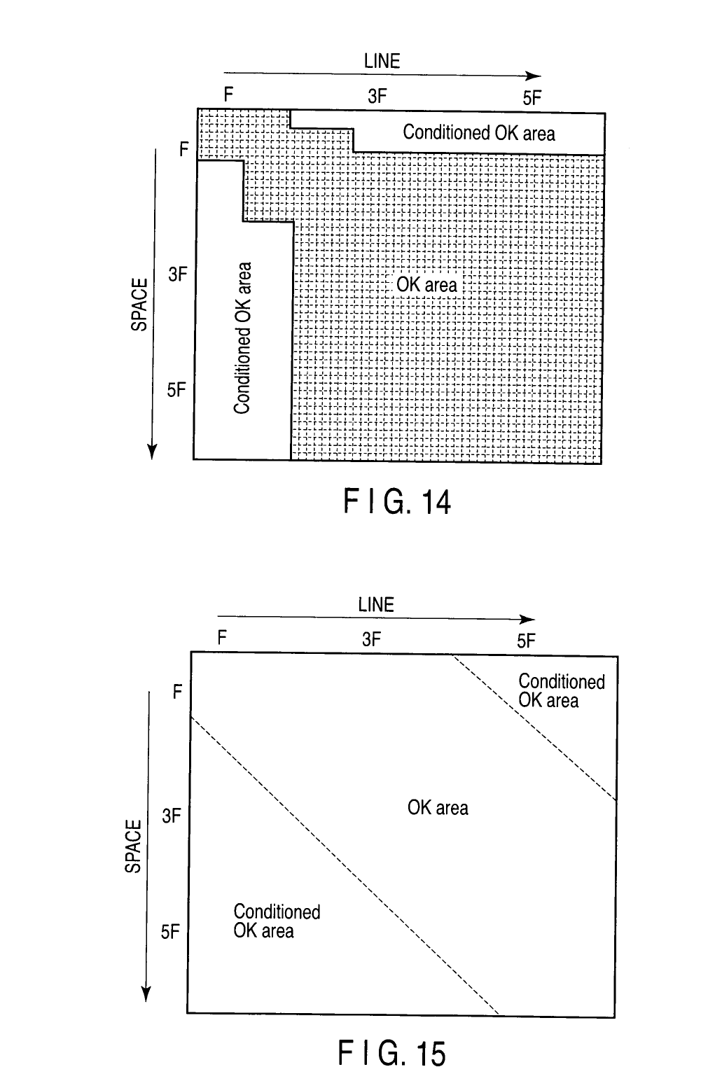

Specifically, FIG. 14 shows the relationship between a line width and a space of a processed pattern of a line, and a line width and a space width are shown as F therein. In this case, it is easy to secure an exposure margin with, for example, the following line pitches having equal line and space: line pitch 2F (line F, space F); line pitch 4F (line 2F, space 2F); line pitch 6F (line 3F, space 3F).

Conversely, if the line and space are not equal, for example, the following line pitches are given: line pitch 4F (line 3F, space F); line pitch 4F (line F, space 3F). In this case, it is general that an exposure margin is reduced compared with the case where the line and space are equal.

The exposure margin is not necessarily equal in the case where the line width is great while the space is narrow and in the case where the line width is small while the space is wide. For this case, there is the case where one of the two cases is advantageous.

A line is extended (thinned out of) at double pitch from a plurality of patterns having a fixed pitch and space. For example, a plurality of first patterns having line F and space F (line pitch 2F) is connected with a plurality of second patterns as an extended line having line F and space 3F (line pitch 4F). In this case, a lithographic margin is largely reduced in a portion where the pitch is different by a factor of two.

According to the case where the line width is small while the space is wide, it is advantageous to improve a lithographic margin. Therefore, the line pitch is set double, and thereby, the layout is defined as a layout with which it is easy to secure an exposure margin.

FIG. 15 shows the relationship of a design rule related to the line width and space. The case where a line width is great while a space is narrow is advantageous in lithography in order to secure a lithographic margin of a processed pattern. In this case, according to the layout, a portion where the space is ⅓ of the line is generated. For this reason, the layout is not the optimum layout for providing the line pitch of the second pattern twice that of the first pattern.

In view of the circumstances, according to this embodiment, the following proposal is made in the case where a line width is great while a space is narrow is advantageous in lithography. Namely, the optimum layout for providing a pitch of an extended line twice that of a line arranged at a fixed pitch is proposed.

Moreover, according to this embodiment, a layout pattern having a sufficient margin is formed using the face that a lithographic margin is sufficiently secure even if a part of a pattern lithographed at an equal pitch is lack.

### First Embodiment

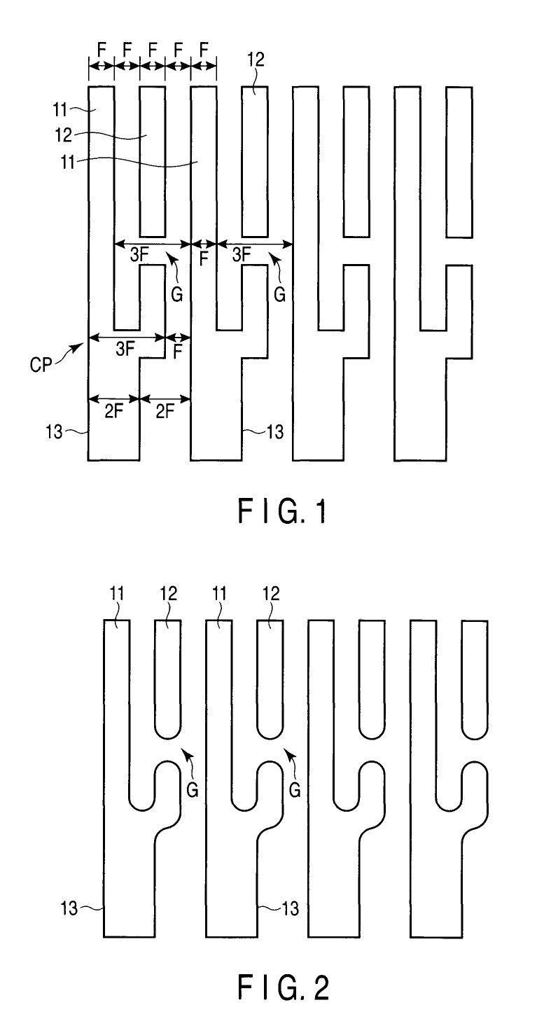

FIGS. 1 and 2 show a first embodiment. FIG. 1 shows a mask pattern (ideal processed pattern of lines). FIG. 2 shows a line pattern obtained using an optical simulation.

FIGS. 1 and 2 show the case where a line pattern having a small width is connected to a line pattern having a width greater than the pattern. Specifically, FIGS. 1 and 2 show the case where a wider line is alternately connected to a plurality of lines having a small width. In FIGS. 1 and 2, lines having a small width are shown as first and second lines 11 and 12, and further, a line having a great width is shown as a third line 13.

The first and second lines 11 and 12 each have a width F. Further, these first and second lines 11 and 12 are arranged in parallel. Furthermore, a space between first and second lines is set to F.

The third line 13 is connected to one edge portion of the first line 11 while being connected to one edge portion of the second line 12 and to the side thereof. The second line 12 has a gap G at its part, for example, near the third line 13. For this reason, the third line 13 is not electrically connected to the second line 12.

According to the first embodiment, the gap G of each second line 12 is formed at the same position. For example, the width of the gap G is set to F. Moreover, a space between third lines 13 is set to 2F. The second line 12, that is, a portion connected to the third line 13 functions as a dummy for improving lithographic characteristics.

According to the configuration, a connection portion CP of first and third lines 11 and 13 is connected with a part of the second line 12. Therefore, in the connection portion CP, there is no combination of line width F and space 3F. In other words, the connection portion CP of first to third lines 11 to 13 has the configuration that the line width is 3F while the space is F. Therefore, the connection portion CP is configured combining OK areas shown in FIGS. 14 and 15. This serves to improve a disconnection margin in the connection portion CP of the first line 11 having a small line width and the third line 13 having a width greater than the first line 11.

According to the first embodiment, the first line 11 having a small line width is connected with the third line 13 having a width greater than the first line 11. In this case, the side portion of the second line 12 partially having a gap G is connected to the side portion of the third line 13. Therefore, it is possible to improve a lithographic margin in the connection portion CP of first and third lines 11 and 13. As can be seen from FIG. 2, this serves to prevent a generation of disconnection failure in first and third lines 11 and 13.

### Second Embodiment

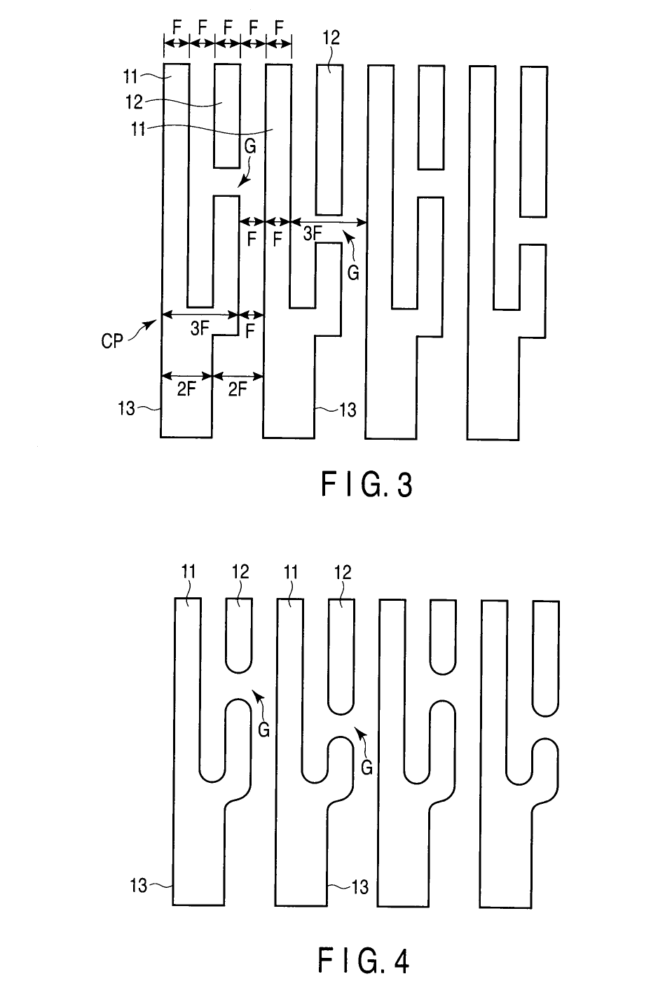

FIGS. 3 and 4 show a second embodiment. According to the first embodiment, the gap G of the second line 12 is formed at the same position in the arrangement direction of first and second lines 11 and 12. In contrast, according to the second embodiment, each gap G of two second lines 12 arranged via the first line 11 is different in its position. Specifically, the gap G is formed at the same position every 4 space, for example.

According to the first embodiment shown in FIG. 1, the gap G is formed at the same position every 2 space. For this reason, the relationship between two first lines 11 adjacent to the gap G meets the condition (line F, space 3F) shown in FIGS. 14 and 15. As a result, there is the possibility of giving a bad influence to a lithographic margin depending on an exposure condition.

In contrast, according to the second embodiment shown in FIGS. 3 and 4, the gap G and neighboring one first line 11 have the relationship that the gap G is formed at the same position every 4 space. This serves to reduce the risk of meeting the condition (line F, space 3F) shown in FIGS. 14 and 15 compared with the first embodiment.

According to the second embodiment, it is possible to improve a lithographic margin in the connection portion CP like the first embodiment. In addition, according to the second embodiment, the gap G of the second line 12 is formed so that it is arranged at the same position every 4 space. Therefore, this serves to prevent a generation of a disconnection failure in the first line 11 adjacent to the gap G.

### Third Embodiment

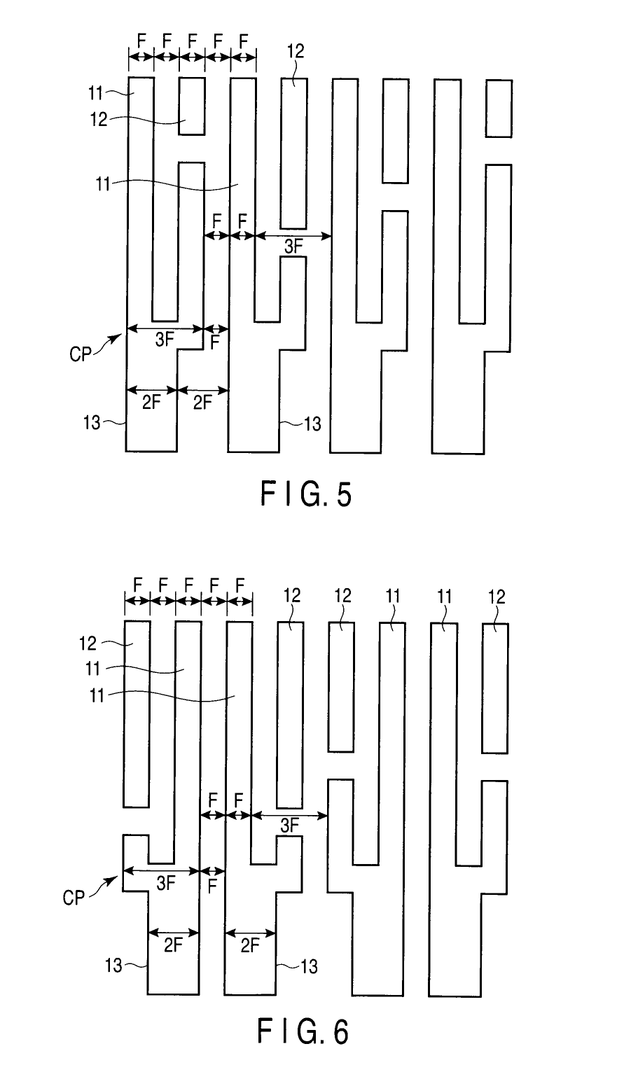

FIG. 5 shows a third embodiment. According to the third embodiment, a gap G of a second line 12 is successively shifted in its position so that it is formed at the same position every 6 space.

According to the third embodiment, it is possible to improve a lithographic margin in the connection portion CP like the first embodiment. In addition, according to the third embodiment, the gap G of the second line 12 is formed so that it is arranged at the same position every 6 space. Therefore, this serves to further improve a lithographic margin in the connection portion CP compared with the second embodiment, and to prevent a generation of a disconnection failure in the first line 11.

### Fourth Embodiment

FIG. 6 shows a fourth embodiment. The first to third embodiments relate to the case where a line having a greater width is alternately connected to a plurality of lines having a small width. In contrast, the fourth embodiment relates to the case where a line having a greater width is connected every two lines having a small width.

As can be seen from FIG. 6, first and second lines 11 and 12 are alternately arranged two by two. A gap G of neighboring second line 12 is formed at the different position. The connection relationship between first to third lines 11 to 13 is the same as the first to third embodiments.

According to the fourth embodiment, a connection portion CP has the configuration that the line width is 3F and a space between connection portions CP is F. Therefore, it is possible to improve a lithographic margin in the connection portion CP. As a result, this serves to reduce a disconnection failure of lines in the connection portion CP.

### Fifth Embodiment

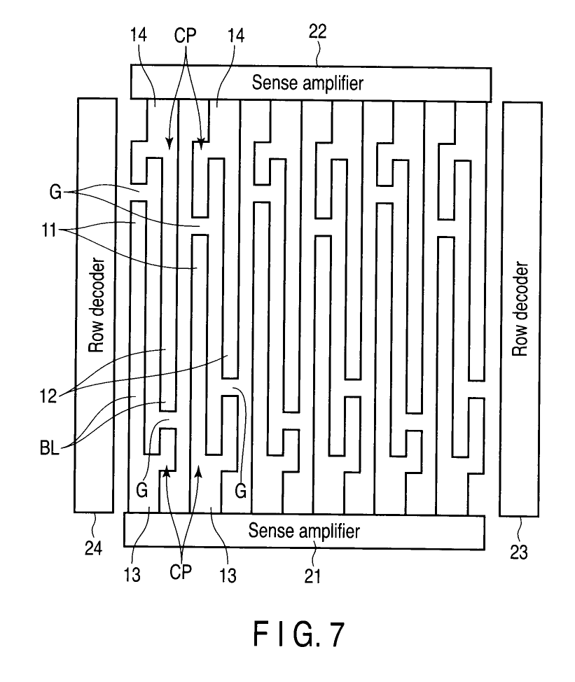

FIG. 7 shows a fifth embodiment, and relates to the case where the configuration shown in the second embodiment is applied to a bit line of a semiconductor memory device, for example, a NAND flash memory.

As shown in FIG. 7, first and second lines 11 and 12 function as a bit line BL. The first line 11 is connected to a sense amplifier 21 via a third line 13. The second line 12 is connected to a sense amplifier 22 via a fourth line 14. The fourth line 14 has a width 2F as well as the third line 13. A space between fourth lines 14 is set to 2F. The side portion of one end portion of the first line 11 is connected to the side portion of the fourth line 14. The other end portion of the first line 11 has a gap G as well as the second line 12. Therefore, the first line 11 is not electrically connected to the sense amplifier 22.

According to the fifth embodiment, the first line 11 functioning as a bit line BL is connected to the sense amplifier 21 via the third line 13. The second line 12 functioning as a bit line BL is connected to the sense amplifier 21 via the fourth line 13. A connection portion CP of first and third lines 11 and 13 and a connection portion CP of second and fourth lines 12 and 14 both have a width 3F and space F. Therefore, a lithographic margin of the connection portion CP is sufficiently secured; as a result, this serves to prevent a disconnection of first and second lines 11 and 12 functioning as a bit line BL.

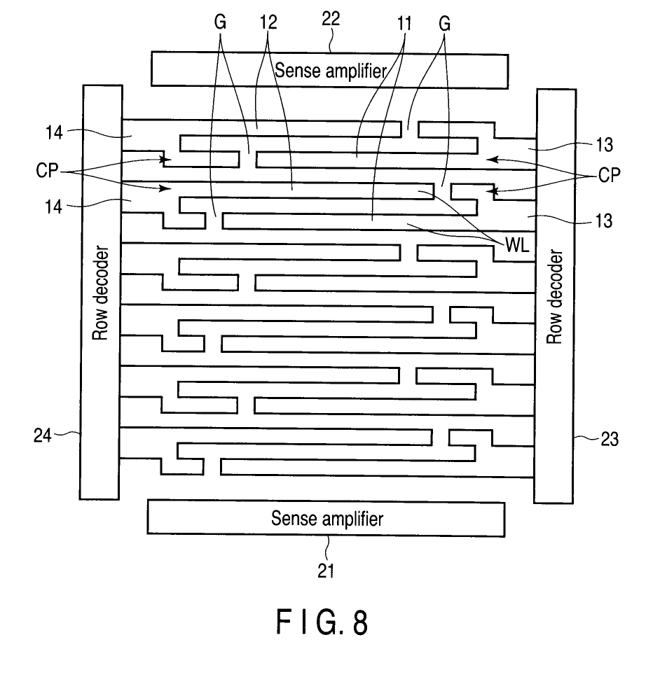

FIG. 8 shows the case where the configuration shown in the second embodiment is applied to a word line of a semiconductor memory device, for example, a NAND flash memory. In FIG. 8, the same reference numerals are used to designate portions identical to FIG. 7.

In FIG. 8, first and second lines 11 and 12 function as a word line WL. The first line 11 is connected to a row decoder 23 via a third line 13. The second line 12 is connected to a sense amplifier 22 via a row decoder 24. The fourth line 14 has a width 2F as well as the third line 13. A space between fourth lines 14 is set to 2F. The side portion of one end portion of the first line 11 is connected to the side portion of the fourth line 14. The other end portion of the first line 11 has a gap G as well as the second line 12. Therefore, the first line 11 is not electrically connected to the row decoder 24.

According to the configuration, it is possible to improve a lithographic margin of word line WL, and to prevent a disconnection of the word line WL.

### Sixth Embodiment

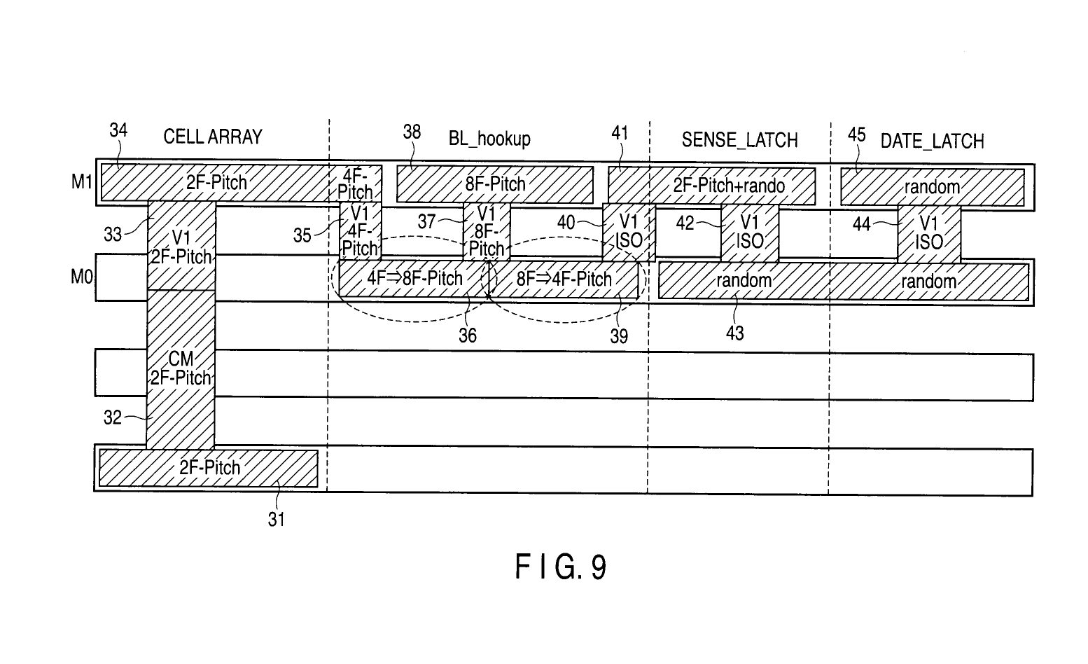

FIG. 9 shows one example of the line structure of a semiconductor memory device, for example, a NAND flash memory. For example, in a memory cell array (CELL ARRAY), a bit line is connected to third and fourth lines 13 and 14 having a double (2F) pitch as described before. In FIG. 9, a line 31 corresponds to third and fourth lines 13 and 14. The line 31 is connected to a line 34 of a metal line layer M1 via a contact metal 32 and a via 33. The line 34 is connected to a line 36 of a metal line layer M0 under line layer M1 by way of a via 35 in a bit line hookup area (BL_hookup). The line 36 is extended, and has a quadruple (4F) pitch. The line 36 having a quadruple pitch is alternately connected to a line 38 of line layer M1 by way of a via 37. Further, the line 36 is extended, and has an octuple (8F) pitch. Furthermore, the remainder of the line 36 is connected to a line 39 thinned to the octuple (8F) pitch in the same layer.

The line 39 is connected to a line 41 of line layer M1 by way of a via 40 in a sense amplifier area (SENSE_LATCH). For example, the line is also connected to the line 41 of the sense amplifier area. The line 41 of the sense amplifier area is connected to a line 43 of line layer M0 by way of a via 42. The line 43 is a line, which is thinned at random. Further, the line 43 is connected to a line 45 of a data latch area (DATA_LATCH) of line layer M1 by way of a via 44.

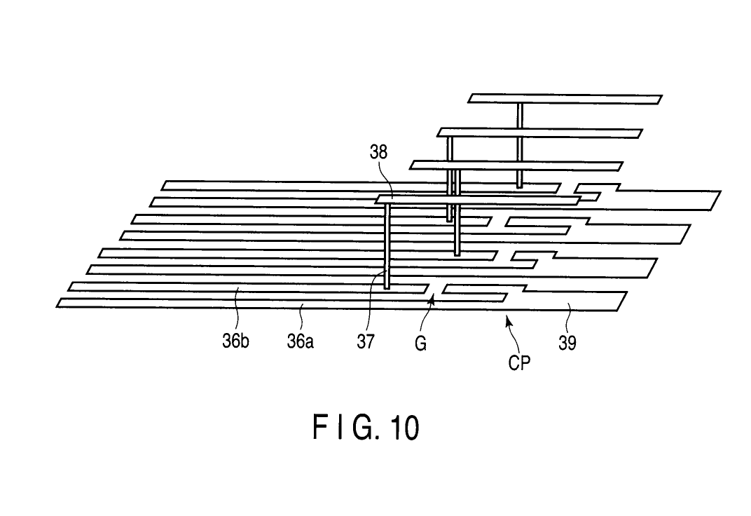

FIGS. 10 and 11 show the structure of a part of the bit line hookup area. In FIGS. 10 and 11, the same reference numerals are used to designate the same portion as FIG. 9. In the manner described above, the each embodiment is applicable to the case where lines are thinned and a pitch between lines is extended. FIGS. 10 and 11 show the case of applying the second embodiment.

Specifically, the line 39 connected to a line 36a is set to a width of two times as much as the line 36a. The side portion of the line 39 is connected with a side portion of a line 36b. The line 36b has a gap G, and therefore, is not electrically connected to the line 39. Further, the line 36b is connected to the line 38 by way of the via 37.

According to the sixth embodiment, a connection portion CP of lines 36a and 39 has the same configuration as the first to fifth embodiments. Therefore, even if lines are thinned, it is possible to improve a lithographic margin in the connection portion CP, and thus, to prevent a disconnection of lines.

FIG. 12 shows a modification example of the sixth embodiment. The modification example relates to the case where a line 51 formed in the same line layer as the line 36a is connected to a line 53 formed in a line layer above the line 38. Lines 51 and 53 are connected by way of a via 52. The line 51 is not connected to the line 39 as well as a line 36a. The end portion of the line 51 has a width of twice that of the line 51, and the side portion thereof is connected to a side portion of a line 36b. The line 36b has a gap G, and therefore, the line 51 is not electrically connected to the line 36b.

According to the modification example, the end and side portions of the line 51 are connected to the side portion of the line 36b. Therefore, it is possible to improve a lithographic margin of the end portion of the line 51.

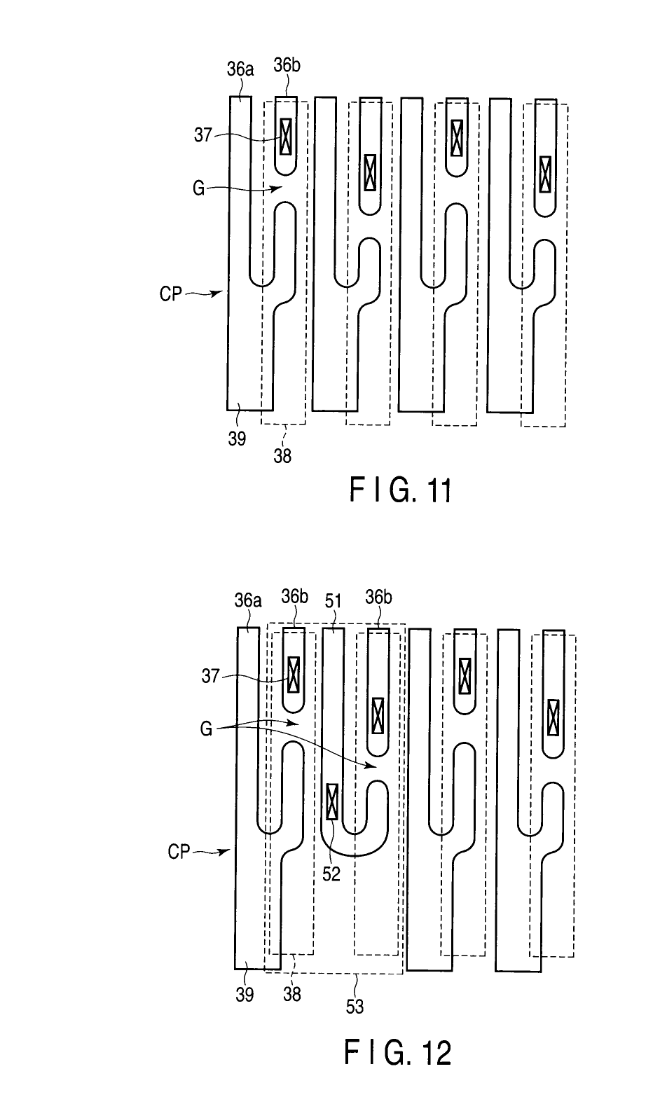

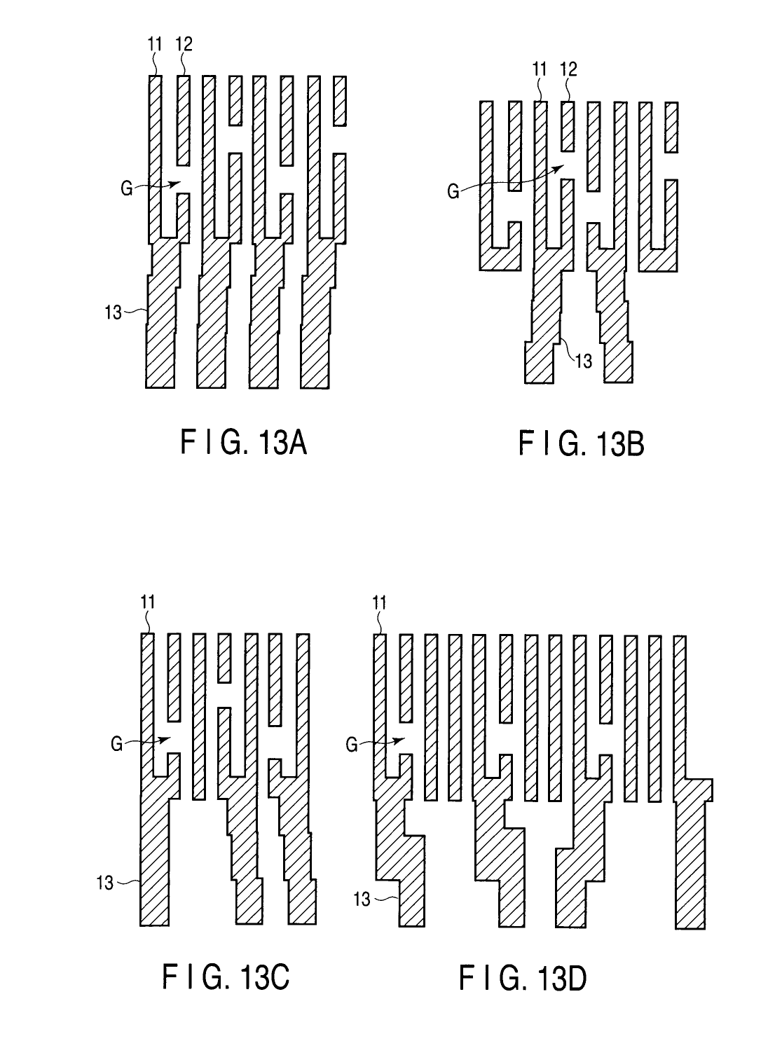

FIGS. 13A to 13D show the case where lines having a great width are connected to a plurality of lines having a small width so that they are thinned. FIG. 13A shows the second embodiment, that is, the case where a line having a great width is connected to a line having a small width at a double pitch. FIG. 13B shows the case where a wide line is connected to a line having a small width at a pitch different from the case of FIG. 13A. FIG. 13C shows the case where a wide line is connected to a line having a small width at random. The configuration shown in FIG. 13C is applicable to lines of the sense latch area and the data latch area shown in FIG. 9. FIG. 13D shows the case where a wide line is connected to a line having a small width at random. The configuration shown in FIG. 13D is applicable to lines of the sense latch area and the data latch area shown in FIG. 9.

In FIGS. 13A to 13D, a side portion of a third line is connected to a side portion of a second line having a gap G in a connection portion CP connecting first and third lines. In this way, the same effect as the each embodiment is obtained.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a first line;
a second line having a width equal to the first line, the second line being arranged with a space equal to the width from the first line, and partially having a gap; and
a third line connected to one end of the first line and connected to a side of one end of the second line.

2. The device according to claim 1, further comprising:
fourth and fifth lines arranged in parallel with the first and second line, the fourth and fifth lines having a line width and a space width between lines, which are equal to the first and second lines, the fifth line partially having a gap; and
a sixth line connected to one end of the fourth line and connected to a side of one end of the fifth line.

3. The device according to claim 2, wherein the gap of the fifth line is formed at the same position as the gap of the second line.

4. The device according to claim 2, wherein a connection portion of the first to third lines has a width of three times as much as the first line, and a connection portion of the fourth to sixth lines has a width of three times as much as the first line, and further, a width between neighboring connection portions is equal to the width of the first line.

5. The device according to claim 2, wherein a portion of the second line connected to the third line and a portion of the fifth line connected to the sixth line are a dummy pattern.

6. The device according to claim 2, wherein the width of the gap of the second line is equal to the width of the second line, and the width of the gap of the fifth line is equal to the width of the fifth line.

7. The device according to claim 2, wherein the gap of the fifth line is formed at a position different from the gap of the second line.

8. The device according to claim 7, wherein the gap of the fifth line and the gap of the second line are formed every 4 space.

9. The device according to claim 7, wherein the gap of the fifth line and the gap of the second line are formed every 6 space.

10. The device according to claim 1, further comprising:
seventh to ninth lines arranged symmetrically with respect to the first line via a space, the seventh to ninth lines having the same shape as the first to third lines.

11. The device according to claim 2, wherein the first, second, fourth and fifth lines are a bit line.

12. The device according to claim 2, wherein the first, second, fourth and fifth lines are a word line.

13. The device according to claim 5, wherein portions of the second line other than the dummy pattern are connected to a tenth line by way of a via.

14. A semiconductor device comprising:
a first line functioning as a first bit line, the first line partially having a gap;
a second line functioning as a second bit line having a width equal to the first line, the second line being arranged with a space equal to the width from the first line, and partially having a gap;
a third line connected to one end of the first line and connected to a side of one end of the second line, the other end of the second line being not electrically connected to the third line by the gap;
a fourth line connected to the other end of the second line and connected to a side of one end of the first line, the other end of the first line being not electrically connected to the fourth line by the gap;
a first circuit connected to the third line; and
a second circuit connected to the fourth line.

15. The device according to claim 14, wherein the first and second circuits are a sense amplifier.

16. The device according to claim 14, wherein the first and second circuits are a row decoder.

17. The device according to claim 2, wherein the third line has a width equal to the sum of the width of the first line and the width of the space, and the sixth line has a width equal to the third line.

18. The device according to claim 14, wherein the third line has a width equal to the sum of the width of the first line and the width of the space and the fourth line has a width equal to the sum of the width of the first line and the width of the space.
